(19) United States
(12) Patent Application Publication
(10) Pub. No.: US 2008/0251826 A1
(43) Pub. Date: Oct. 16, 2008

(54) MULTI-LAYER SEMICONDUCTOR STRUCTURE AND MANUFACTURING METHOD THEREOF

(75) Inventors: Jack Lee, Hsinchu County (TW); Herbert Lu, Hsinchu City (TW); Marvin Liu, Hsinchu City (TW); Peter Pong, Hsinchu County (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 11/747,527

(22) Filed: May 11, 2007

(30) Foreign Application Priority Data
Apr. 16, 2007 (TW) 096113281

(51) Int. Cl. H01L 27/108; H01L 21/46

(52) U.S. Cl. 257/301; 257/306; 257/315; 438/455; 438/458; 257/E27.084; 257/E21.482

(57) ABSTRACT

A method for manufacturing a multi-layer semiconductor structure is disclosed. First, a first wafer comprising a first semiconductor device structure and a second wafer comprising a substrate and a single crystal silicon layer are provided, and the first and second wafers are combined in which a surface of the first wafer having the first semiconductor device structure is in contact with a surface of the second wafer having the single crystal silicon layer. A glue layer and a dielectric layer can be employed to combine the first and second wafers. Afterwards, a process for manufacturing a second semiconductor device structure is performed on the single crystal silicon layer.

### BACKGROUND OF THE INVENTION

(A) Field of the Invention

The present invention relates to a semiconductor structure and manufacturing method thereof, and more specifically, to a multi-layer semiconductor structure and manufacturing method thereof using wafer-bonding technology

(B) Description of the Related Art

With continuing improvements in semiconductor technology, line width gradually shrinks to increase integration density. However, as devices become closer, manufacture becomes more difficult and integration density is limited. Moreover, some problems such as crosslink, timing delay and thermal effect may occur.

Consequently, a double-layer semiconductor structure in combination with two wafers is generated. In addition to increasing the density of devices, different semiconductor structures may be integrated for various applications. U.S. Pat. No. 6,423,613 discloses a process in which semiconductor structures are formed in two wafers first, and the two wafers are bonded and annealed afterwards.

Wafer bonding has a problem of common interface defects; the majority of the interface defects are voids. Interface defects may occur in the bonding process, during long-term storage, under heat treatment or in the wafer grinding process. The defects occurring in bonding may be caused by residual particles, surface convexity, insufficient bonding filler or residual gases at the interface. If the wafers are stored for a long time before bonding, or heat-treated after bonding, interface defects may be caused by reaction of bonding filler and substrate, damage to surface bonding, or contamination or peeling of bonding surface or interface. Therefore, yield and reliability of devices are decreased. Moreover, different glue conditions may generate bubbles on a glue interface and therefore decrease yield of the gluing process. Excessive glue pressure may break wafers. Also, wafers may break during heat treatment due to large differences between thermal expansion coefficients of bonding materials.

In view of the risks of wafer bonding and the formation of semiconductor structures on wafers needing to undergo more than one hundred processes, problems occurring during wafer bonding can nullify all previous efforts and lead to increases in manufacturing cost.

### SUMMARY OF THE INVENTION

The present invention provides a multi-layer semiconductor structure and manufacturing method thereof, with a view to increasing device density, and providing various semiconductor structures to increase diversity of device design. Moreover, manufacturing scrap expense due to defects in wafer bonding can be avoided.

In accordance with the present invention, a multi-layer semiconductor structure is manufactured as follows. First, a first wafer including a first semiconductor device structure and a second wafer including a substrate and a single crystal silicon layer are provided. The first and second wafers are bonded, in which a surface of the first wafer having the first semiconductor device structure is in contact with a surface of the second wafer having the single crystal silicon layer. The first wafer and the second wafer can be bonded by a dielectric layer and a glue layer. Then, the single crystal silicon layer is subjected to processes to form a second semiconductor device structure thereon.

Preferably, the single crystal silicon layer can be formed by ion implantation, grinding, etching and polishing. After bonding the first and second wafers, the substrate of the second wafer is removed by ion implantation, grinding and etching.

The first and second semiconductor device structures can be manufactured as desired; they can be the same or different semiconductor devices. As an example, the first semiconductor device structure may be a memory structure and the second semiconductor device structure may be a logic device structure, so as to form an embedded memory structure. Alternatively, the first semiconductor device structure may be a dynamic random access memory (DRAM) structure of deep trench type and the second semiconductor device structure may be a DRAM structure of stack type. The process to form the second semiconductor device structure comprises the formation of conductive lines connecting the first and second semiconductor device structures to bit lines on a surface of the substrate of the first wafer, so as to control operations of the first and second semiconductor device structures.

### BRIEF DESCRIPTION OF THE DRAWINGS

FIG. 1 illustrates wafer bonding for a multi-layer semiconductor structure in accordance with the present invention;

FIGS. 2-7 illustrate a method for manufacturing a multi-layer semiconductor structure in accordance with the present invention; and

FIGS. 8-12 illustrate a method for manufacturing a double-layer DRAM structure in accordance with an embodiment of the present invention.

### DETAILED DESCRIPTION OF THE INVENTION

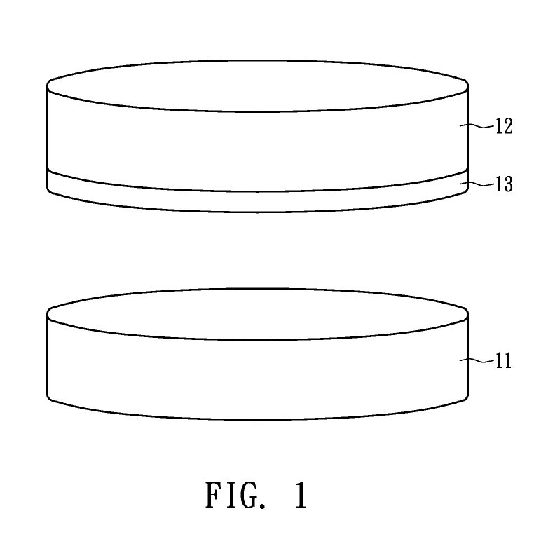

FIG. 1 illustrates the manufacturing method of a multi-layer semiconductor structure in accordance with the present invention, in which two wafers 11 and 12 are combined by wafer bonding technology. A glue layer 13 is between the wafers 11 and 12. The wafer 11 includes a fabricated semiconductor device structure, whereas the wafer 12 serves as a substrate for forming another semiconductor device structure. The two wafers 11 and 12 include either similar semiconductor device structures, e.g., DRAMs, or different semiconductor device structures, e.g., a logic device structure and a DRAM structure; or a memory circuit and a solar cell circuit, thereby providing diversity of combinations. The semiconductor device structures of the first and second wafers can be selected from the group consisting of DRAM structure of deep trench type, DRAM structure of stack type, logic device structure and flash memory structure.

Manufacture of a memory structure is exemplified as follows:

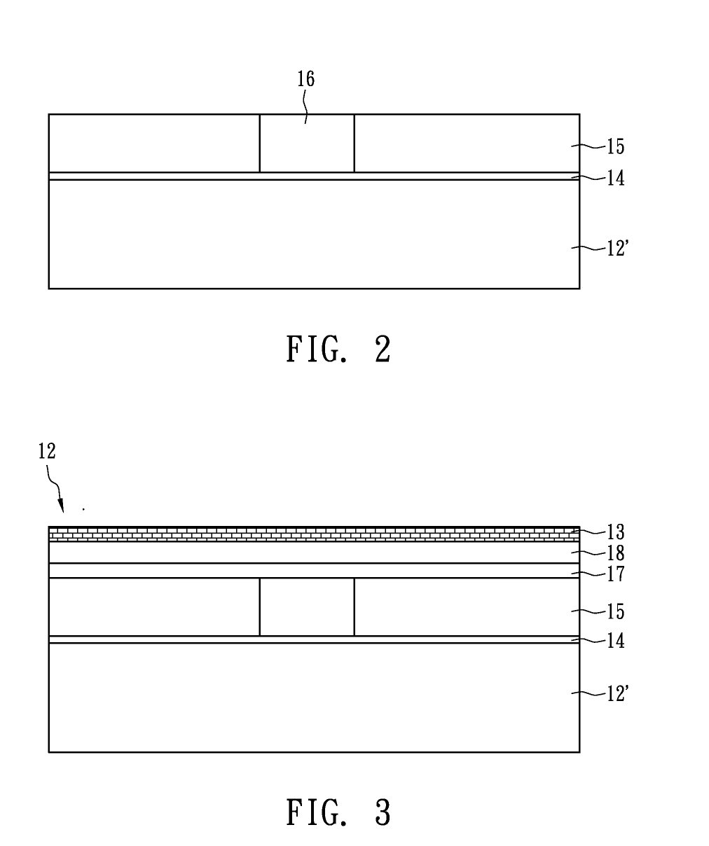

Referring to FIG. 2, an etch stop layer 14 and a single crystal silicon layer 15 are formed on a substrate 12′ by ion implantation. The etch stop layer 14 can be silicon oxide (SiO₂) or silicon oxynitride (SiON), and the thickness is preferably less than 0.1 μm. The single crystal silicon layer 15 can be formed by ion implantation, grinding, etching and polishing, and comprises alignment windows 16 therein, which may be made of SiO₂ formed by ion implantation, for aligning the first and second semiconductor device structures in a lithography process. Sequentially, dielectric layers 17 and 18 and a glue layer 13 are formed on a surface of the single crystal silicon layer 15, so as to form the wafer 12 as shown in FIG. 3. In this embodiment, the dielectric layer 17 is SiON of a thickness of 150 to 200 angstroms, the dielectric layer 18 is borophosphosilicate glass (BPSG) or BPSG/TEOS (Tetraethoxysilane), and the glue layer 13 includes titanium (Ti) with a thickness of approximately 100 angstroms.

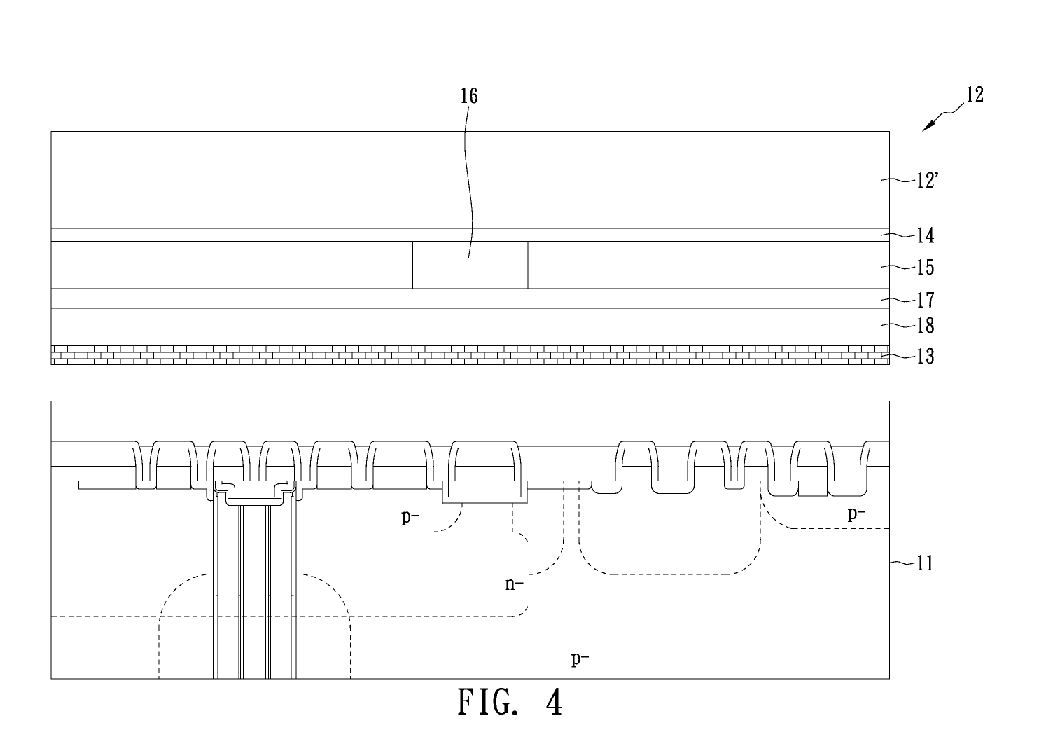

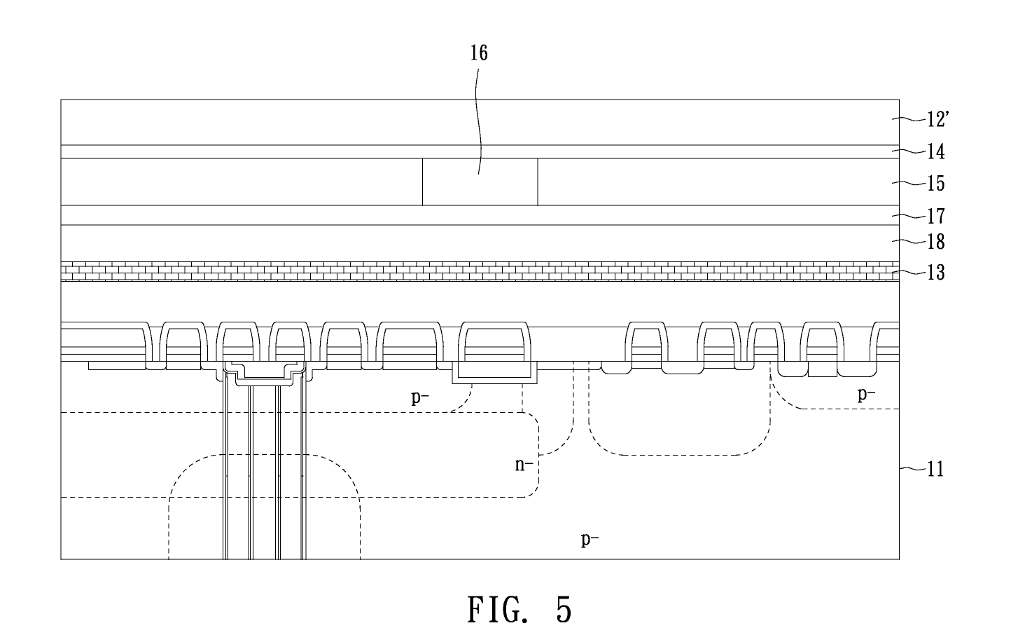

Referring to FIG. 4, a semiconductor device structure, e.g., a DRAM structure of deep trench type, has been fabricated in the lower wafer 11, and the wafer 12 is upside down and bonded with the wafer 11 by the glue layer 13 and the dielectric layer 18 in vacuum. Then, the substrate 12′ is ground to a thickness of 100 μm, as shown in FIG. 5.

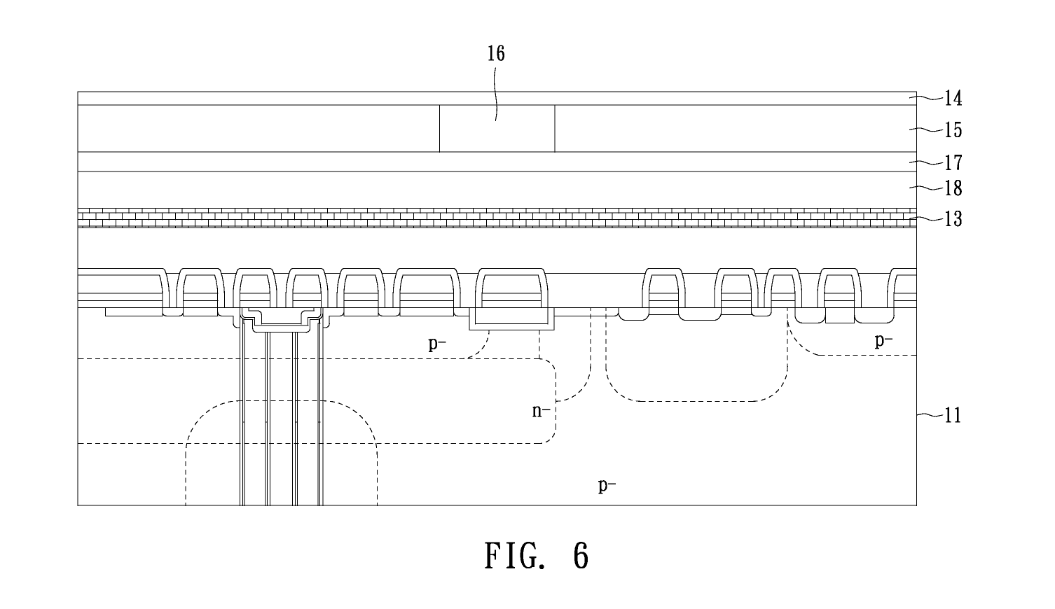

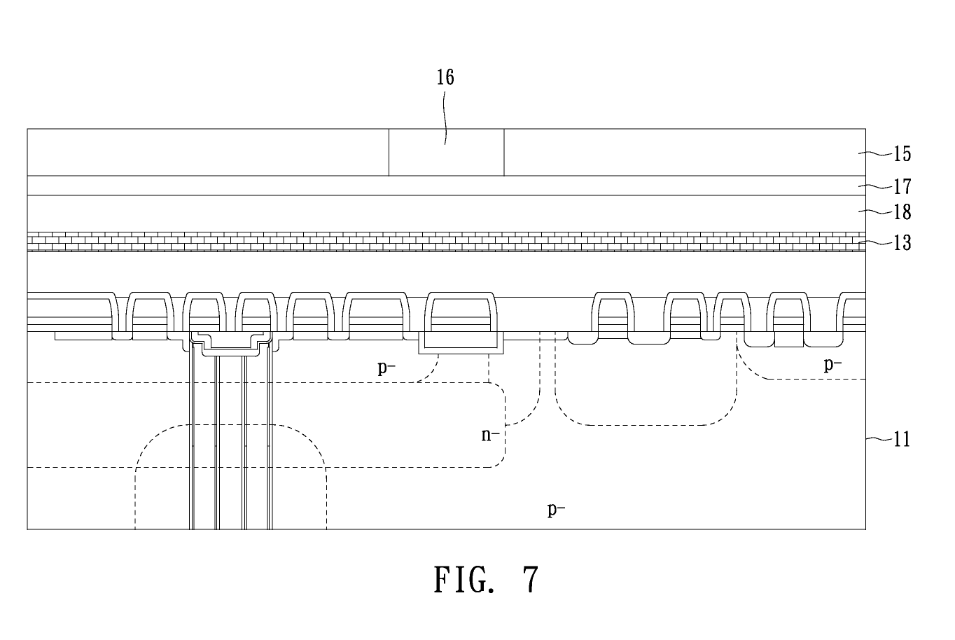

Referring to FIG. 6, the wafer substrate 12′ is removed to the etch stop layer 14 by ion implantation, grinding and etching (e.g., potassium hydroxide (KOH) wet etching). Then, the etch stop layer 14 is removed by etching and polishing, and SiO₂ in the alignment window 16 is removed by hydrofluoric (HF) acid as shown in FIG. 7. As a result, the single crystal silicon wafer 15 is formed for manufacturing the second semiconductor device structure thereon. In other words, the second semiconductor device structure is formed after wafer bonding, i.e., formed by an in-situ process.

The second semiconductor device structure of DRAM of stack type is exemplified as follows.

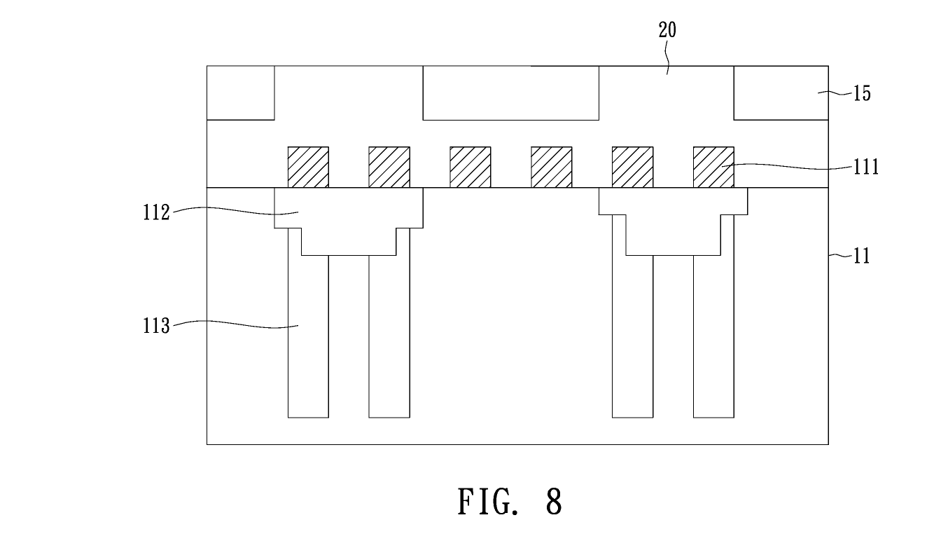

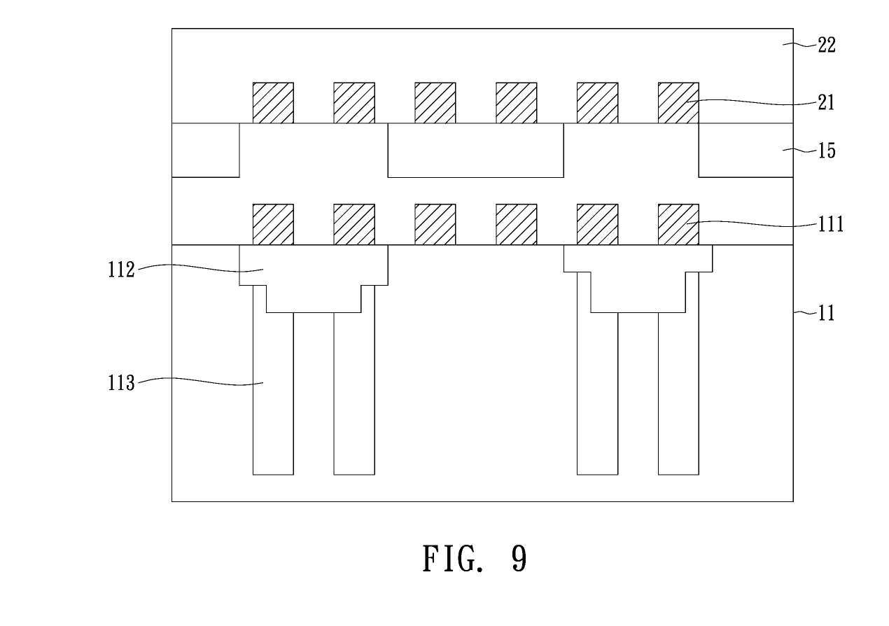

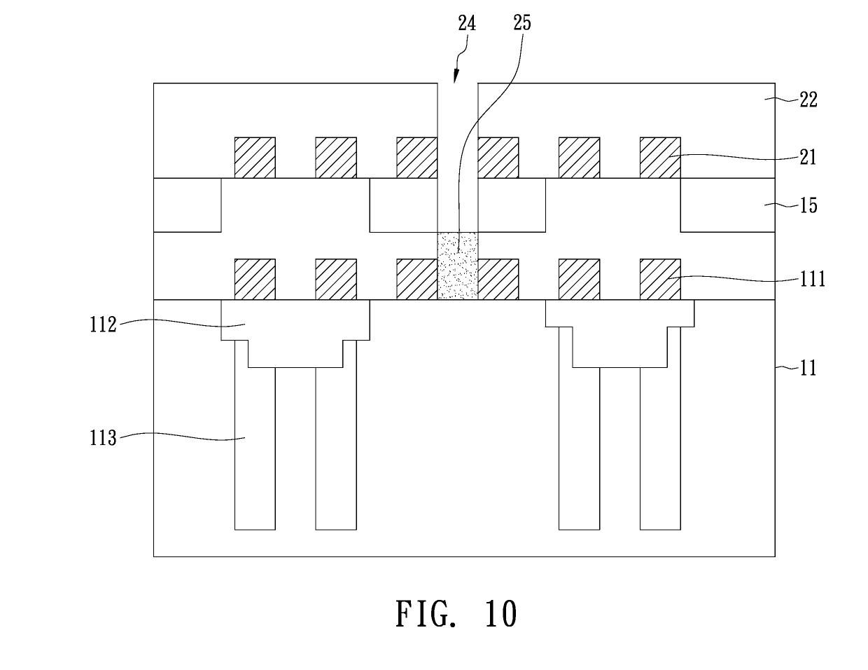

Referring to FIG. 8, the wafer 11 includes shallow trench isolations (STI) 112 and deep-trench capacitors 113, and gates 111 are formed thereon. After wafers are bonded, isolation layers 20, e.g., STI, are formed in the single crystal silicon layer 15 to isolate active areas, and then gates 21 and a dielectric layer 22 are formed thereon as shown in FIG. 9.

Referring to FIG. 10, a contact hole 24 connecting to silicon substrate surface of the wafer 11 is formed by etching, and followed by filling a conductive plug 25.

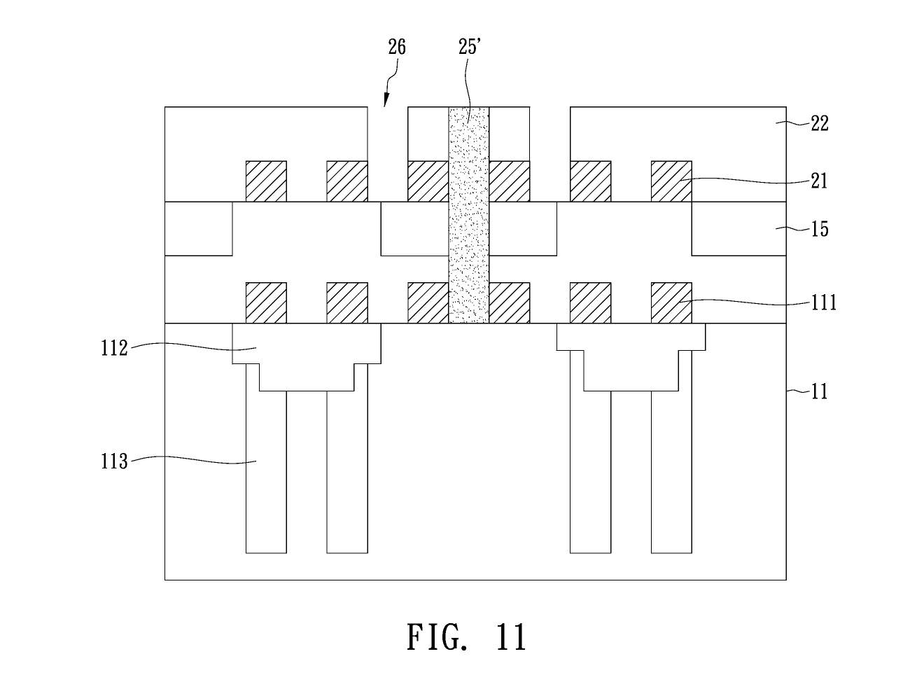

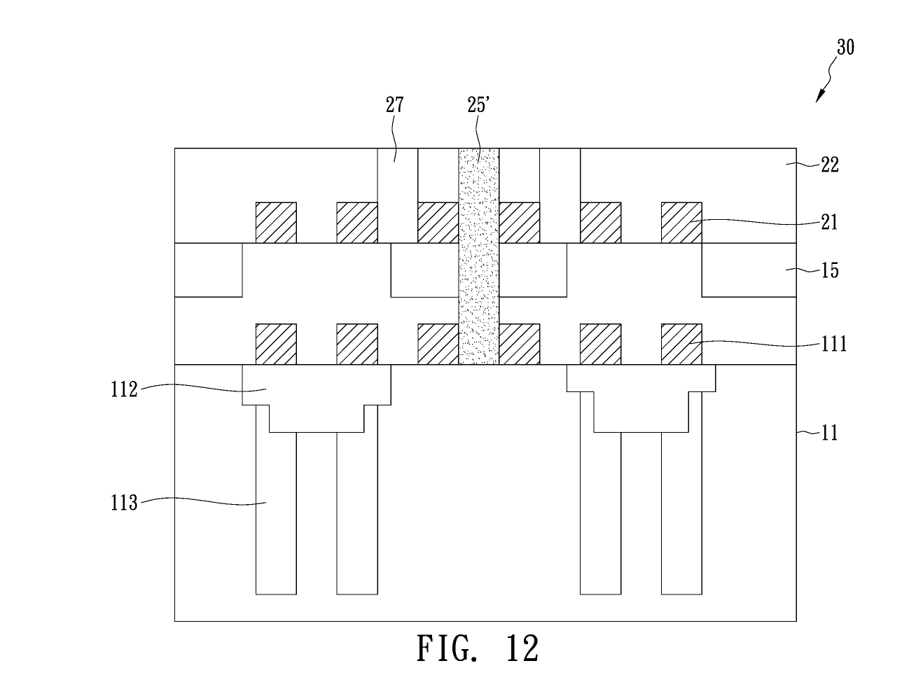

Referring to FIG. 11, capacitor openings 26 are formed by etching. Because the conductive plug 25 is in the contact hole 24 during the etching process, the silicon substrate can be protected to avoid silicon loss. Afterwards, a conductive line 25′ fills the contact hole 24, so that the upper gates 21 and lower gates 111 commonly use the bit lines of the lower wafer 11 and form a contact to bit line (CB) structure. Then, stack capacitors 27 are formed, and as a result a multi-layer semiconductor structure (double-layer DRAM) 30 is formed as shown in FIG. 12. The conductive line 25′ electrically connecting the upper and lower DRAM structures controls the operations of the upper and lower gates.

In consideration of high temperature process for making semiconductor device structure in the upper wafer after bonding, metal lines of the lower wafer can be of tungsten or copper with higher melting points to avoid thermal cycle problems.

A semiconductor device structure of two layers is exemplified in the above embodiment. Nevertheless, the same process can be repeated to manufacture a multi-layer structure of three or more layers as desired.

The above-described embodiments of the present invention are intended to be illustrative only. Numerous alternative embodiments may be devised by those skilled in the art without departing from the scope of the following claims.

What is claimed is:

1. A method for manufacturing a multi-layer semiconductor structure, comprising:
providing a first wafer including a first semiconductor device structure;
providing a second wafer including a substrate and a single crystal silicon layer;
bonding the first and second wafers in which a surface of the first wafer having the first semiconductor device structure is in contact with a surface of the second wafer having the single crystal silicon layer; and
making a second semiconductor device structure on the single crystal silicon layer.

2. The method for manufacturing a multi-layer semiconductor structure in accordance with claim 1, wherein the first and second semiconductor device structures are memory structures.

3. The method for manufacturing a multi-layer semiconductor structure in accordance with claim 1, wherein the single crystal silicon layer is formed by ion implantation, grinding, etching and polishing.

4. The method for manufacturing a multi-layer semiconductor structure in accordance with claim 1, wherein the first and second wafers are bonded by a dielectric layer and a glue layer.

5. The method for manufacturing a multi-layer semiconductor structure in accordance with claim 1, wherein the second wafer further comprises an etch stop layer formed between the substrate and the single crystal silicon layer.

6. The method for manufacturing a multi-layer semiconductor structure in accordance with claim 1, wherein after the first and second wafers are bonded, the substrate of the second wafer is removed by ion implantation, grinding and etching.

7. The method for manufacturing a multi-layer semiconductor structure in accordance with claim 6, wherein after the substrate of the second wafer is removed, the etch stop layer is removed by etching or polishing so that the single crystal silicon layer is exposed for performing processes of the second semiconductor device structure thereon.

8. The method for manufacturing a multi-layer semiconductor structure in accordance with claim 1, wherein the first semiconductor device structure is one of a DRAM structure of deep trench type, a DRAM structure of stack type, a logic device structure and a flash memory structure.

9. The method for manufacturing a multi-layer semiconductor structure in accordance with claim 1, wherein the second semiconductor device structure is one of a DRAM structure of deep trench type, a DRAM structure of stack type, a logic device structure and a flash memory structure.

10. The method for manufacturing a multi-layer semiconductor structure in accordance with claim 1, wherein making the second semiconductor device comprises formation of a conductive line connecting the first and second semiconductor device structures to bit lines on a surface of the substrate of the first wafer, so as to control operations of the first and second semiconductor device structures.

11. The method for manufacturing a multi-layer semiconductor structure in accordance with claim 1, wherein metal lines of the first semiconductor device structure comprise tungsten or copper.

12. A multi-layer semiconductor structure, comprising:
a wafer comprising a first semiconductor device structure;
a single crystal silicon layer formed on a surface of the first semiconductor device structure;
a second semiconductor device structure formed on the single crystal silicon layer after the first semiconductor device structure is formed; and
at least one conductive line connecting the first and second semiconductor device structures to bit lines on a surface of the wafer, so as to control operations of the first and second semiconductor device structures.

13. The multi-layer semiconductor structure in accordance with claim 12, wherein the first semiconductor device structure is one of a DRAM structure of deep trench type, a DRAM structure of stack type, a logic device structure and a flash memory structure.

14. The multi-layer semiconductor structure in accordance with claim 12, wherein the second semiconductor device structure is one of a DRAM structure of deep trench type, a DRAM structure of stack type, a logic device structure and a flash memory structure.

15. The multi-layer semiconductor structure in accordance with claim 12, further comprising a dielectric layer and a glue layer between the single crystal silicon layer and the first semiconductor device structure.

16. The multi-layer semiconductor structure in accordance with claim 12, wherein the dielectric layer comprises silicon oxynitride, borophosphosilicate glass/Tetraethoxysilane, and the glue layer includes titanium.

17. The multi-layer semiconductor structure in accordance with claim 12, wherein metal lines of the wafer comprise tungsten or copper.
